(19) United States
(12) Patent Application Publication
(10) Pub. No.: US 2025/0293187 A1
(43) Pub. Date: Sep. 18, 2025

(54) SEMICONDUCTOR DEVICE AND METHOD OF MANUFACTURING THE SAME

(71) Applicant: Renesas Electronics Corporation, Tokyo (JP)

(72) Inventors: Shinji TOJO, Tokyo (JP); Toshiaki SHIRONOUCHI, Tokyo (JP); Nobuhiro KINOSHITA, Tokyo (JP); Tatsuaki TSUKUDA, Tokyo (JP)

(21) Appl. No.: 18/973,218

(22) Filed: Dec. 9, 2024

(30) Foreign Application Priority Data
Mar. 12, 2024 (JP) 2024-037935

(51) Int. Cl. H01L 23/00; H01L 21/56; H01L 23/544; H01L 25/065

(52) U.S. Cl. CPC H01L 24/06; H01L 21/565; H01L 23/544; H01L 24/32; H01L 24/83; H01L 25/0657; H01L 24/48; H01L 24/73; H01L 2223/54426; H01L 2224/06051; H01L 2224/32145; H01L 2224/32225; H01L 2224/48149; H01L 2224/48229; H01L 2224/73265; H01L 2224/8313; H01L 2224/83191; H01L 2224/83862; H01L 2225/06506; H01L 2225/0651; H01L 2225/06593; H01L 2924/1424

(57) ABSTRACT

A semiconductor device includes a first semiconductor chip, a die attach film, a second semiconductor chip, and a resin molding member. The first semiconductor chip is attached to the second semiconductor chip via the die attach film. The second semiconductor chip includes an analog circuit, a bonding pad, and one or more deformed bonding pads serving as alignment marks of the first semiconductor chip. In plan view, the analog circuit is located inside an outer peripheral edge of the die attach film. The resin molding member seals the first semiconductor chip, the second semiconductor chip, and the die attach film.

### CROSS-REFERENCE TO RELATED APPLICATIONS

The disclosure of Japanese Patent Application No. 2024-037935 filed on Mar. 12, 2024 including the specification, drawings and abstract is incorporated herein by reference in its entirety.

### BACKGROUND

The present disclosure relates to a semiconductor device and a method of manufacturing the same, and can be suitably used for, for example, a system-in-package type semiconductor device and a method of manufacturing the same.

There are disclosed techniques listed below.
[Patent Document 1] Japanese Unexamined Patent Application Publication No. 2014-132682
[Patent Document 2] Japanese Unexamined Patent Application Publication No. 2006-222147

Patent Document 1 discloses a method of manufacturing a resin-sealed type semiconductor device. The method of manufacturing the resin-sealed type semiconductor device disclosed in Patent document 1 includes a step of preparing a wiring board and a step of mounting a semiconductor chip on the wiring board. The wiring board includes a plurality of pads and an alignment target having an L-shape. In the step of mounting the semiconductor chip on the wiring board, the alignment target is recognized, the semiconductor chip is aligned with the wiring board, and then the semiconductor chip is mounted on the wiring board.

Patent Document 2 discloses a semiconductor device. The semiconductor device described in Patent Document 2 includes a bonding pad and a recognition mark provided separately from the bonding pad. The bonding pad includes a probing flaw forming region and a bonding region. The probing flaw forming region and the bonding region are configured to be distinguishable from each other based on the planar shape of the recognition mark.

### SUMMARY

As a resin-sealed type semiconductor device, a system-in-package type semiconductor device in which a plurality of semiconductor chips stacked via a die attach film is resin-sealed has been known. When the outer peripheral edge of the die attach film overlaps an analog circuit of the semiconductor chip located below the die attach film among the plurality of semiconductor chips in plan view seen in the stacking direction of the plurality of semiconductor chips, stress is applied to the analog circuit, and the analog circuit may not operate normally. Other problems and novel features will be apparent from the description of this specification and the accompanying drawings.

According to one embodiment, a semiconductor device includes a first semiconductor chip, a die attach film provided on the first semiconductor chip, a second semiconductor chip, and a resin molding member. The first semiconductor chip is attached to the second semiconductor chip via the die attach film. The second semiconductor chip includes an analog circuit, a bonding pad, and one or more deformed bonding pads, a shape of the one or more deformed bonding pads being different from a shape of the bonding pad. The one or more deformed bonding pads are alignment marks of the first semiconductor chip. In plan view seen in the stacking direction of the first semiconductor chip and the die attach film, the analog circuit is located inside the outer peripheral edge of the die attach film. The resin molding member seals the first semiconductor chip, the second semiconductor chip, and the die attach film.

According to one embodiment, a method of manufacturing a semiconductor device includes a step of providing a die attach film on a first semiconductor chip, and a step of aligning the first semiconductor chip with a second semiconductor chip. The second semiconductor chip includes an analog circuit, a bonding pad, and one or more deformed bonding pads, a shape of the one or more deformed bonding pads being different from a shape of the bonding pad. In the step of aligning the first semiconductor chip with the second semiconductor chip, the first semiconductor chip is aligned with the second semiconductor chip such that the analog circuit is located inside the outer peripheral edge of the die attach film in plan view seen in the stacking direction of the first semiconductor chip and the die attach film while using the one or more deformed bonding pads as alignment marks of the first semiconductor chip. The method of manufacturing a semiconductor device includes a step of attaching the first semiconductor chip to the second semiconductor chip via the die attach film, and a step of providing a resin molding member sealing the first semiconductor chip, the second semiconductor chip, and the die attach film.

According to the above embodiment, it is possible to provide a semiconductor device capable of securing normal operation of an analog circuit.

### BRIEF DESCRIPTION OF THE DRAWINGS

FIG. 1 is a schematic plan view of a semiconductor device according to a first embodiment.

FIG. 2 is a schematic sectional view taken along the sectional line II-II illustrated in FIGS. 1 and 11, of the semiconductor device according to the first embodiment and a semiconductor device according to a second embodiment.

FIG. 3 is a flowchart illustrating a method of manufacturing the semiconductor devices according to the first embodiment and the second embodiment, and semiconductor devices according to a fourth embodiment and a fifth embodiment.

FIG. 4 is a schematic plan view illustrating a step of aligning a first semiconductor chip with a second semiconductor chip in the method of manufacturing the semiconductor device according to the first embodiment.

FIG. 5 is a schematic sectional view taken along the sectional line V-V in FIGS. 4 and 12, illustrating a step of aligning the first semiconductor chip with the second semiconductor chip in the method of manufacturing the semiconductor devices according to the first embodiment and the second embodiment.

FIG. 6 is a schematic sectional view illustrating a resin molding step in the method of manufacturing the semiconductor device according to the first embodiment.

FIG. 7 is a schematic plan view of a semiconductor device according to a modification of the first embodiment.

FIG. 8 is a schematic sectional view taken along the sectional line VIII-VIII in FIG. 7, of the semiconductor device according to the modification of the first embodiment.

FIG. 9 is a schematic plan view illustrating a step of aligning a first semiconductor chip with a second semiconductor chip in a method of manufacturing the semiconductor device according to the modification of the first embodiment.

FIG. 10 is a schematic sectional view taken along the sectional line X-X in FIG. 9, illustrating the step of aligning the first semiconductor chip with the second semiconductor chip in the method of manufacturing the semiconductor device according to the modification of the first embodiment.

FIG. 11 is a schematic plan view of a semiconductor device according to the second embodiment.

FIG. 12 is a schematic plan view illustrating a step of aligning a first semiconductor chip with a second semiconductor chip in a method of manufacturing the semiconductor device according to the second embodiment.

FIG. 13 is a schematic plan view of a semiconductor device according to a third embodiment.

FIG. 14 is a schematic sectional view taken along the sectional line XIV-XIV in FIG. 13, of the semiconductor device according to the third embodiment.

FIG. 15 is a diagram illustrating a flowchart of a method of manufacturing the semiconductor device according to the third embodiment.

FIG. 16 is a schematic plan view illustrating a step of aligning a first semiconductor chip with a second semiconductor chip in the method of manufacturing the semiconductor device according to the third embodiment.

FIG. 17 is a schematic sectional view taken along the sectional line XVII-XVII in FIG. 16, illustrating the step of aligning the first semiconductor chip with the second semiconductor chip in the method of manufacturing the semiconductor device according to the third embodiment.

FIG. 18 is a schematic plan view of a semiconductor device according to the fourth embodiment.

FIG. 19 is a schematic sectional view taken along the sectional line XIX-XIX illustrated in FIG. 18, of the semiconductor device according to the fourth embodiment.

FIG. 20 is a schematic sectional view illustrating one step of a step of providing a die attach film on a first semiconductor chip in a method of manufacturing the semiconductor device according to the fourth embodiment.

FIG. 21 is a schematic sectional view illustrating a step subsequent to the step illustrated in FIG. 20 in the step of providing the die attach film on the first semiconductor chip in the method of manufacturing the semiconductor device according to the fourth embodiment.

FIG. 22 is a schematic sectional view illustrating a step subsequent to the step illustrated in FIG. 21 in the step of providing the die attach film on the first semiconductor chip in the method of manufacturing the semiconductor device according to the fourth embodiment.

FIG. 23 is a schematic plan view illustrating a step of aligning the first semiconductor chip with a second semiconductor chip in the method of manufacturing the semiconductor device according to the fourth embodiment.

FIG. 24 is a schematic sectional view taken along the sectional line XXIV-XXIV in FIG. 23, illustrating the step of aligning the first semiconductor chip with the second semiconductor chip in the method of manufacturing the semiconductor device according to the fourth embodiment.

FIG. 25 is a schematic plan view of a semiconductor device according to the fifth embodiment.

FIG. 26 is a schematic sectional view taken along the sectional line XXVI-XXVI illustrated in FIG. 25, of the semiconductor device according to the fifth embodiment.

FIG. 27 is a schematic sectional view of a semiconductor device according to a first modification of the fifth embodiment.

FIG. 28 is a schematic sectional view of a semiconductor device according to a second modification of the fifth embodiment.

### DETAILED DESCRIPTION

Hereinafter, a semiconductor device according to an embodiment will be described. Note that the same components are denoted by the same reference numerals, and the description thereof will not be repeated.

### First Embodiment

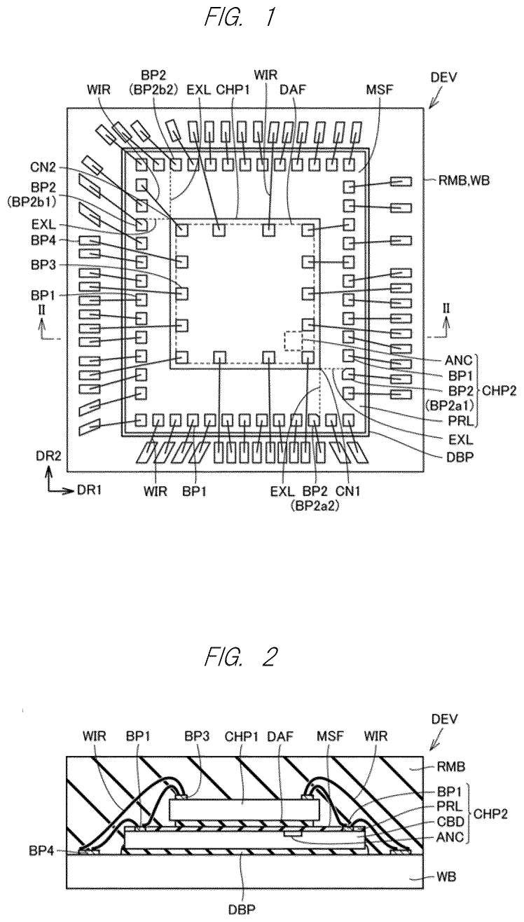

A configuration of a semiconductor device DEV according to a first embodiment will be described with reference to FIGS. 1 and 2. The semiconductor device DEV of the present embodiment is, for example, a system-in-package (SiP) type semiconductor device. The configuration of a semiconductor package is, for example, a land grid array (LGA) type semiconductor device. The semiconductor device DEV mainly includes a first semiconductor chip CHP1, a die attach film DAF, a second semiconductor chip CHP2, a resin molding member RMB, a wiring board WB, and a conductive wire WIR.

The first semiconductor chip CHP1 is not particularly limited, and may be, for example, an application specific integrated circuit (ASIC) chip. The first semiconductor chip CHP1 includes a plurality of bonding pads BP3. The plurality of bonding pads BP3 is formed on a main surface of the first semiconductor chip CHP1, which is opposite to a main surface thereof facing the second semiconductor chip CHP2. The plurality of bonding pads BP3 is formed of, for example, a conductive material such as copper (Cu) or aluminum (Al). The first semiconductor chip CHP1 includes a first corner CN1 and a second corner CN2 located diagonally to the first corner CN1. The outer peripheral edge of the first semiconductor chip includes an outer peripheral edge portion extending in a first direction DR1 and an outer peripheral edge portion extending in a second direction DR2 intersecting the first outer peripheral edge portion. The second direction DR2 is, for example, perpendicular to the first direction DR1.

The die attach film DAF is provided on the first semiconductor chip CHP1. For example, the die attach film DAF is attached to the first semiconductor chip CHP1. The storage elastic modulus of the die attach film DAF at 150° C. is 20 MPa or less. The storage elastic modulus of the die attach film DAF at 150° C. may be 50 MPa or less, or may be 20 MPa or less.

The second semiconductor chip CHP2 is not particularly limited, but is, for example, a motor driver. The operation of the second semiconductor chip CHP2 is controlled by the first semiconductor chip CHP1. The second semiconductor chip CHP2 controls a motor (not illustrated).

The second semiconductor chip CHP2 has a main surface MSF. The main surface MSF extends along the first direction DR1 and the second direction DR2 intersecting the first direction DR1. The second semiconductor chip CHP2 includes a chip main body CBD, an analog circuit ANC, a plurality of bonding pads BP1, and one or more deformed bonding pads BP2. The second semiconductor chip CHP2 may further include a protective layer PRL.

The chip main body CBD is formed of, for example, a semiconductor material such as silicon (Si) or silicon carbide (SiC).

The analog circuit ANC is formed on the surface of the chip main body CBD on the side of the main surface MSF. The analog circuit ANC is, for example, an operational amplifier or a constant current circuit, and is an electric circuit sensitive to stress.

The plurality of bonding pads BP1 and the one or more deformed bonding pads BP2 are formed on the surface of the chip main body CBD on the side of the main surface MSF. The bonding pad BP1 and the one or more deformed bonding pads BP2 are formed of, for example, a conductive material such as copper (Cu) or aluminum (Al).

The one or more deformed bonding pads BP2 have a shape different from the shape of the bonding pad BP1. For example, in a plan view seen in the stacking direction of the first semiconductor chip CHP1 and the die attach film DAF (hereinafter, simply referred to as “plan view”), the bonding pad BP1 has a rectangular shape, and the one or more deformed bonding pads BP2 have a rectangular shape with a chamfered corner. The one or more deformed bonding pads BP2 may have a rectangular shape with a rounded corner. The number of the one or more deformed bonding pads BP2 is smaller than the number of the plurality of bonding pads BP1. The second semiconductor chip CHP2 may include a plurality of the deformed bonding pads BP2. In the present embodiment, the second semiconductor chip CHP2 includes four deformed bonding pads BP2.

The one or more deformed bonding pads BP2 are alignment marks of the first semiconductor chip CHP1. That is, the first semiconductor chip CHP1 is aligned with the second semiconductor chip CHP2 using the one or more deformed bonding pads BP2 as alignment marks.

In plan view, an extension line EXL of the outer peripheral edge of the one or more deformed bonding pads BP2 deviates from the analog circuit ANC. In plan view, the extension line EXL of the outer peripheral edge of the one or more deformed bonding pads BP2 extends to the outside of the analog circuit ANC. In plan view, the outer peripheral edge of the first semiconductor chip CHP1 is located on the extension line EXL of the outer peripheral edge of the one or more deformed bonding pads BP2.

For example, the one or more deformed bonding pads BP2 include deformed bonding pads BP2a1 and BP2a2 for alignment of the first corner CN1 of the first semiconductor chip CHP1 and deformed bonding pads BP2b1 and BP2b2 for alignment of the second corner CN2 of the first semiconductor chip CHP1. The deformed bonding pads BP2a1 and BP2a2 include the deformed bonding pad BP2a1 for guiding the outer peripheral edge portion of the first semiconductor chip CHP1 extending in the first direction DR1 and the deformed bonding pad BP2a2 for guiding the outer peripheral edge portion of the first semiconductor chip CHP1 extending in the second direction DR2. The deformed bonding pads BP2b1 and BP2b2 include the deformed bonding pad BP2b1 for guiding the outer peripheral edge portion of the first semiconductor chip CHP1 extending in the first direction DR1 and the deformed bonding pad BP2b2 for guiding the outer peripheral edge portion of the first semiconductor chip CHP1 extending in the second direction DR2.

The protective layer PRL is formed of, for example, an insulating material such as polyimide. The protective layer PRL covers the analog circuit ANC. The bonding pad BP1 and the one or more deformed bonding pads BP2 are exposed from the protective layer PRL. The surface of the protective layer PRL opposite to the chip main body CBD constitutes a part of the main surface MSF.

The first semiconductor chip CHP1 is attached to the main surface MSF of the second semiconductor chip CHP2 via the die attach film DAF. In plan view, the analog circuit ANC is located inside the outer peripheral edge of the die attach film DAF. In plan view, the analog circuit ANC deviates from the outer peripheral edge of the die attach film DAF. In plan view, the outer peripheral edge of the die attach film DAF is located inside the outer peripheral edge of the first semiconductor chip CHP1.

The wiring board WB is, for example, a multilayer wiring board including a plurality of wiring layers. The insulating layer that electrically insulates the adjacent wiring layers from each other is formed of, for example, a prepreg formed by impregnating glass fiber with resin. The plurality of wiring layers is formed of, for example, metal such as copper (Cu). The wiring board WB supports the second semiconductor chip CHP2. For example, the second semiconductor chip CHP2 is fixed to the upper surface of the wiring board WB using a die-bonding paste DBP or a die attach film (not illustrated). The die-bonding paste DBP is, for example, an acrylic resin adhesive. A plurality of bonding pads BP4 is formed on the upper surface of the wiring board WB. A plurality of terminals (not illustrated) is formed on the lower surface of the wiring board WB. Each of the plurality of bonding pads BP4 and the plurality of terminals is formed of, for example, a conductive material such as copper (Cu) or aluminum (Al). The wiring board WB supplies an electric signal to the first semiconductor chip CHP1 and the second semiconductor chip CHP2, and receives an electric signal from the first semiconductor chip CHP1 and the second semiconductor chip CHP2.

The conductive wire WIR is, for example, a metal wire such as a gold wire, a copper wire, or an aluminum wire. The conductive wire WIR is bonded to the bonding pad BP1 or the deformed bonding pad BP2 and the bonding pad BP4 to electrically connect the bonding pad BP1 or the deformed bonding pad BP2 to the bonding pad BP4. The conductive wire WIR is bonded to the bonding pad BP1 or the deformed bonding pad BP2 and the bonding pad BP3 to electrically connect the bonding pad BP1 or the deformed bonding pad BP2 to the bonding pad BP3. The conductive wire WIR is bonded to the bonding pad BP3 and the bonding pad BP4 to electrically connect the bonding pad BP3 to the bonding pad BP4.

The resin molding member RMB seals the first semiconductor chip CHP1, the second semiconductor chip CHP2, and the die attach film DAF. The resin molding member RMB includes, for example, a thermosetting resin and a filler dispersed in the thermosetting resin. The thermosetting resin is, for example, an epoxy resin. The filler is, for example, silica particles. The filler content of the resin molding member RMB is, for example, 70 weight percent or more and 90 weight percent or less.

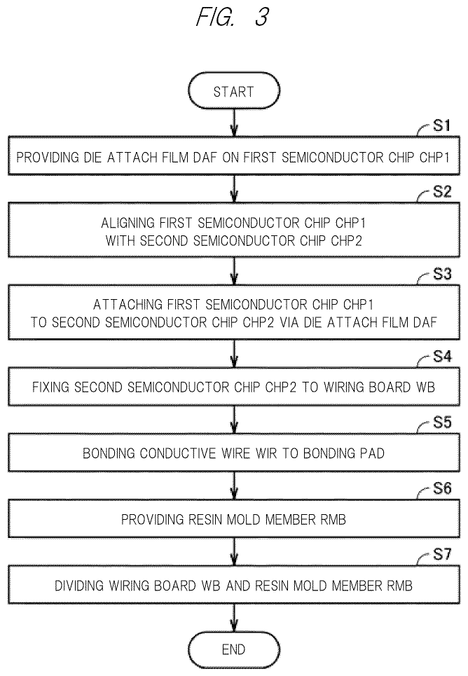

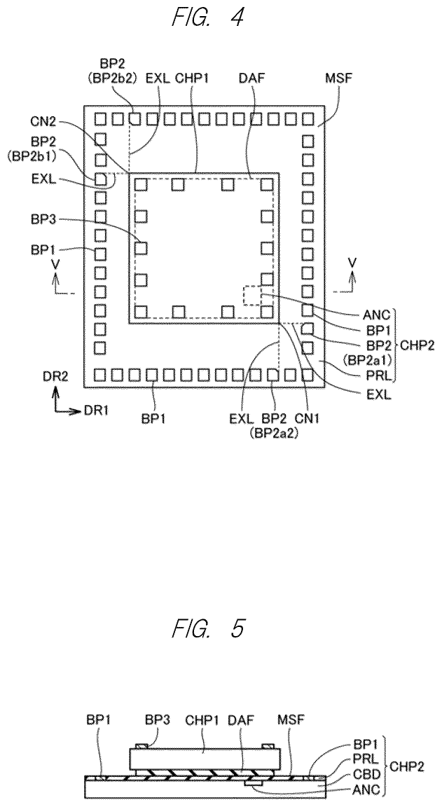

An example of a method of manufacturing the semiconductor device DEV of the present embodiment will be described with reference to FIGS. 3 to 6.

Referring to FIG. 3, the die attach film DAF is provided on the first semiconductor chip CHP1 (step S1). For example, the die attach film DAF is attached to the first semiconductor chip CHP1. The outer peripheral edge of the die attach film DAF is, for example, flush with the outer peripheral edge of the first semiconductor chip CHP1.

Referring to FIGS. 3 to 5, the first semiconductor chip CHP1 is aligned with the second semiconductor chip CHP2 (step S2). Specifically, while using one or more deformed bonding pads BP2 as alignment marks of the first semiconductor chip CHP1, the first semiconductor chip CHP1 is aligned with the second semiconductor chip CHP2 such that the analog circuit ANC is located inside the outer peripheral edge of the die attach film DAF in plan view.

For example, in plan view, the extension line EXL of the outer peripheral edge of the one or more deformed bonding pads BP2 deviates from the analog circuit ANC. The first semiconductor chip CHP1 is aligned with the second semiconductor chip CHP2 such that the outer peripheral edge of the first semiconductor chip CHP1 is located on the extension line EXL of the outer peripheral edge of the one or more deformed bonding pads BP2 in plan view. In this way, the first semiconductor chip CHP1 can be aligned with the second semiconductor chip CHP2 such that the outer peripheral edge of the die attach film DAF deviates from the analog circuit ANC in plan view.

Specifically, the one or more deformed bonding pads BP2 include a plurality of deformed bonding pads BP2a1, BP2a2, BP2b1, and BP2b2. In plan view, the first semiconductor chip CHP1 is aligned with the second semiconductor chip CHP2 such that the first corner CN1 of the first semiconductor chip CHP1 is located on the extension line EXL of the outer peripheral edges of the deformed bonding pads BP2a1 and BP2a2, and the second corner CN2 of the first semiconductor chip CHP1 is located on the extension line EXL of the outer peripheral edges of the deformed bonding pads BP2b1 and BP2b2. For example, the outer peripheral edge portion of the first semiconductor chip CHP1 extending in the first direction DR1 is located on the extension line EXL of the outer peripheral edges of the deformed bonding pads BP2a1 and BP2b1. An outer peripheral edge portion of the first semiconductor chip CHP1 extending in the second direction DR2 is located on the extension line EXL of the outer peripheral edges of the deformed bonding pads BP2a2 and BP2b2.

Referring to FIG. 3, the first semiconductor chip CHP1 is attached to the second semiconductor chip CHP2 via the die attach film DAF (step S3). Specifically, the die attach film DAF is brought into contact with the main surface MSF of the second semiconductor chip CHP2. The die attach film DAF is heated to 150° C. to cure the die attach film DAF. In this manner, the first semiconductor chip CHP1 is attached to the main surface MSF of the second semiconductor chip CHP2 via the die attach film DAF.

Referring to FIG. 3, the second semiconductor chip CHP2 is fixed to the wiring board WB using the die-bonding paste DBP or the die attach film (not illustrated) (step S4). Here, the wiring board WB includes a plurality of package forming regions (not illustrated), and the second semiconductor chip CHP2 is fixed to each of the plurality of package forming regions. In the present embodiment, a description will be given focusing on one package forming region. Further, in the present embodiment, the mounting order in which the second semiconductor chip CHP2 is fixed to the wiring board WB after the first semiconductor chip CHP1 is attached to the second semiconductor chip CHP2 has been described, but the mounting order may be a mounting order in which the first semiconductor chip CHP1 is attached to the second semiconductor chip CHP2 after the second semiconductor chip CHP2 is fixed to the wiring board WB.

Referring to FIG. 3, the conductive wire WIR is bonded to the bonding pad (step S5). In the present embodiment, the conductive wire WIR is bonded to the bonding pads BP1, BP3, and BP4 and the deformed bonding pad BP2.

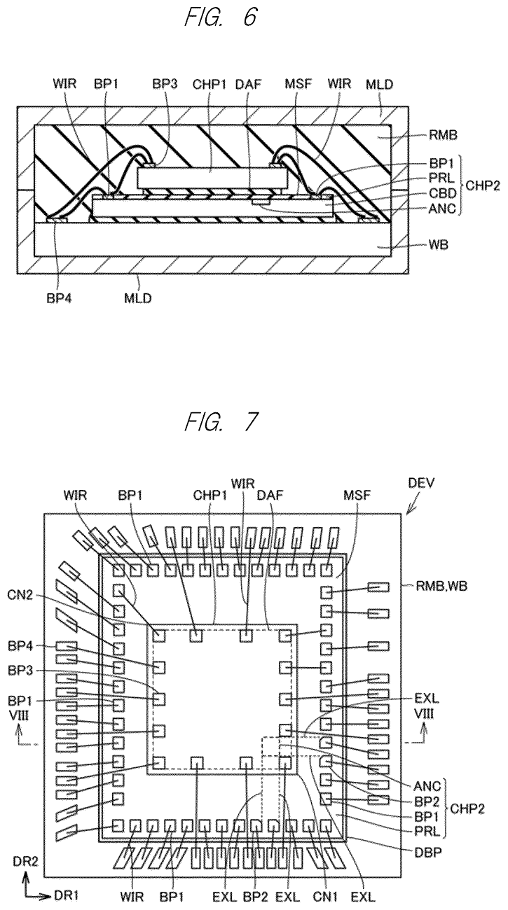

Referring to FIGS. 3 and 6, the resin molding member RMB for sealing the first semiconductor chip CHP1, the second semiconductor chip CHP2, and the die attach film DAF is provided (step S6). For example, a mold MLD is opened, and a stacked body including the first semiconductor chip CHP1, the die attach film DAF, and the second semiconductor chip CHP2 located in each of the plurality of package forming regions is disposed in a cavity of the mold MLD. The mold MLD is closed, and the molding resin is injected into the cavity of the mold MLD to collectively seal the plurality of package forming regions. The molding resin is heated, for example, at a mold temperature (for example, 150° C.) to cure the molding resin. Thus, the resin molding member RMB is formed. In the present embodiment, the land grid array (LGA) type semiconductor device has been described as the configuration of the semiconductor package, but a ball grid array (BGA) type semiconductor device may be used. In the case of the ball grid array (BGA) type semiconductor device, after the resin molding member RMB is formed, a plurality of solder balls is formed on a plurality of terminals, respectively.

Referring to FIG. 3, the wiring board WB and the resin molding member RMB are divided into respective package forming regions, and a stacked body including the first semiconductor chip CHP1, the second semiconductor chip CHP2, and the wiring board WB is divided into individual pieces (step S7). Thus, the semiconductor device DEV of the present embodiment is obtained.

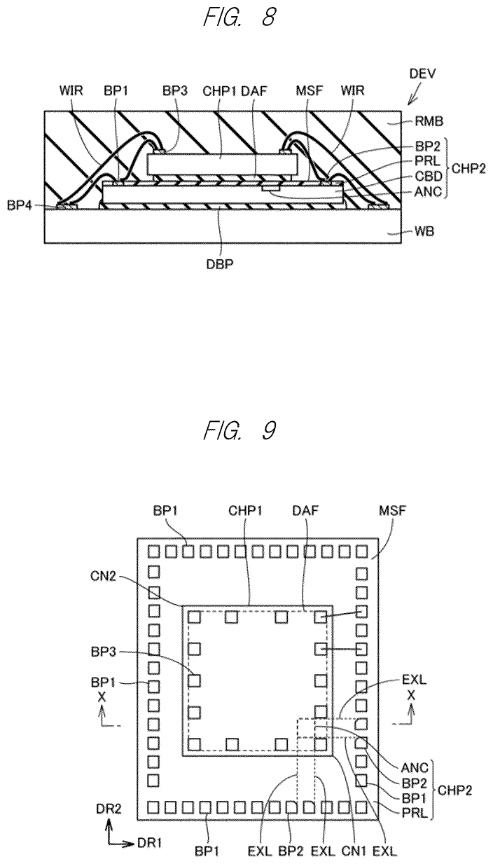

A configuration of a semiconductor device DEV according to a modification of the present embodiment will be described with reference to FIGS. 7 and 8.

In the modification of the present embodiment, the extension line EXL of the outer peripheral edge of the one or more deformed bonding pads BP2 is located on the outer peripheral edge of the analog circuit ANC in plan view. In plan view, the outer peripheral edge of the first semiconductor chip CHP1 deviates from the extension line EXL of the outer peripheral edge of the one or more deformed bonding pads BP2.

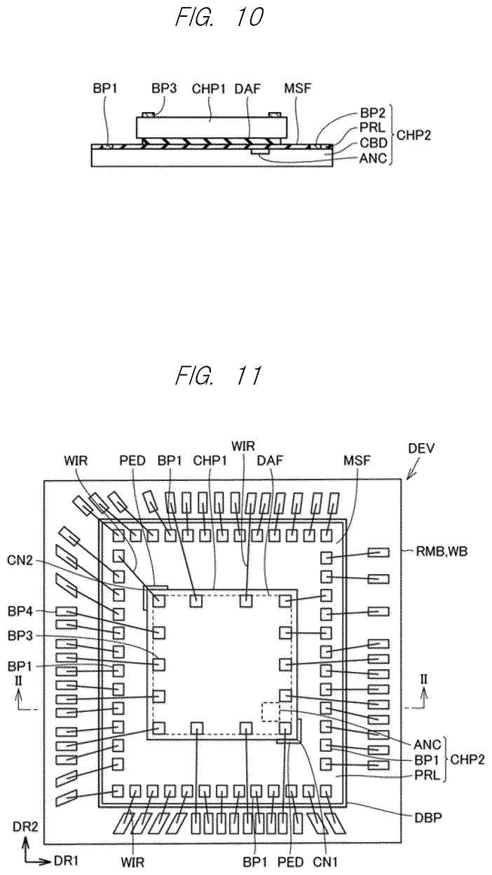

Referring to FIGS. 3, 9, and 10, the example of the method of manufacturing the semiconductor device DEV according to the modification of the present embodiment includes the same steps as those of the example of the method of manufacturing the semiconductor device DEV of the present embodiment, but mainly step S2 is different from the example of the method of manufacturing the semiconductor device DEV of the present embodiment.

In step S2 of the modification of the present embodiment, the first semiconductor chip CHP1 is aligned with the second semiconductor chip CHP2 such that the outer peripheral edge of the first semiconductor chip CHP1 deviates from the extension line EXL of the outer peripheral edge of the one or more deformed bonding pads BP2 in plan view. In this way, the first semiconductor chip CHP1 can be aligned with the second semiconductor chip CHP2 such that the outer peripheral edge of the die attach film DAF deviates from the analog circuit ANC in plan view.

Functions of the semiconductor device DEV of the present embodiment and the modification thereof and the manufacturing method thereof will be described.

Since the storage elastic modulus of the die attach film DAF at the mold temperature (for example, 150° C.) is as small as 20 MPa or less, it is smaller than the injection pressure of molding resin. Therefore, when the molding resin is injected, the die attach film DAF is pushed by the molding resin, resulting in contraction of die attach film. In plan view, the outer peripheral edge of the die attach film DAF is located, for example, inside the outer peripheral edge of the first semiconductor chip CHP1.

However, the first semiconductor chip CHP1 provided with the die attach film DAF is aligned with the second semiconductor chip CHP2 by using the one or more deformed bonding pads BP2 as alignment marks of the first semiconductor chip CHP1. Therefore, the first semiconductor chip CHP1 can be aligned with the second semiconductor chip CHP2 such that the outer peripheral edge of the die attach film DAF deviates from the analog circuit ANC in plan view. For example, the first semiconductor chip CHP1 can be aligned with the second semiconductor chip CHP2 such that a distance between the analog circuit and the outer peripheral edge of the die attach film DAF in plan view is larger than a contraction length of the die attach film DAF in the step of providing the resin molding member RMB (step S6).

Even if the die attach film DAF contracts in the step of providing the resin molding member RMB (step S6), the outer peripheral edge of the die attach film DAF is still located outside the analog circuit ANC in plan view and deviates from the analog circuit ANC. Therefore, the stress applied from the die attach film DAF to the analog circuit ANC decreases. Normal operation of the analog circuit ANC can be secured.

On the other hand, when the outer peripheral edge of the die attach film DAF overlaps the analog circuit ANC in plan view, a large stress difference occurs at an interface between the die attach film DAF and the resin molding member RMB, and thus the operation of the analog circuit ANC becomes abnormal.

Effects of the semiconductor device DEV and the method of manufacturing the same according to the present embodiment will be described.

The semiconductor device DEV of the present embodiment includes the first semiconductor chip CHP1, the die attach film DAF provided on the first semiconductor chip CHP1, the second semiconductor chip CHP2, and the resin molding member RMB. The first semiconductor chip CHP1 is attached to the second semiconductor chip CHP2 via the die attach film DAF. The second semiconductor chip CHP2 includes the analog circuit ANC, the bonding pad BP1, and one or more deformed bonding pads BP2, a shape of the one or more deformed bonding pads BP2 being different from the bonding pad BP1. The one or more deformed bonding pads BP2 are alignment marks of the first semiconductor chip CHP1. In plan view seen in the stacking direction of the first semiconductor chip CHP1 and the die attach film DAF, the analog circuit ANC is located inside the outer peripheral edge of the die attach film DAF. The resin molding member RMB seals the first semiconductor chip CHP1, the second semiconductor chip CHP2, and the die attach film DAF.

The first semiconductor chip CHP1 provided with the die attach film DAF is aligned with the second semiconductor chip CHP2 using the one or more deformed bonding pads BP2 as alignment marks of the first semiconductor chip CHP1. Therefore, the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

In the semiconductor device DEV of the present embodiment, the extension line EXL of the outer peripheral edge of the one or more deformed bonding pads BP2 deviates from the analog circuit ANC in plan view. In plan view, the outer peripheral edge of the first semiconductor chip CHP1 is located on the extension line EXL of the outer peripheral edge of the one or more deformed bonding pads BP2.

Therefore, by using the one or more deformed bonding pads BP2 as alignment marks of the first semiconductor chip CHP1, the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

In the semiconductor device DEV of the present embodiment, the first semiconductor chip CHP1 includes the first corner CN1 and the second corner CN2 located diagonally to the first corner CN1. The one or more deformed bonding pads BP2 include the first deformed bonding pad (deformed bonding pads BP2a1 and BP2a2) and the second deformed bonding pad (deformed bonding pads BP2b1 and BP2b2). The first deformed bonding pad is used for alignment of the first corner CN1. The second deformed bonding pad is used for alignment of the second corner CN2.

Therefore, the first semiconductor chip CHP1 can be two-dimensionally aligned with the second semiconductor chip CHP2. In plan view, the outer peripheral edge of the die attach film DAF can deviate from the analog circuit ANC. An interface between the die attach film DAF and the resin molding member RMB having a large stress difference does not overlap the analog circuit ANC in plan view. Therefore, the normal operation of the analog circuit ANC can be secured.

In the semiconductor device DEV of the present embodiment, the outer peripheral edge of the first semiconductor chip CHP1 includes a first outer peripheral edge portion and a second outer peripheral edge portion extending in a direction intersecting the first outer peripheral edge portion. The one or more deformed bonding pads BP2 include the first deformed bonding pad (deformed bonding pads BP2a1 and BP2b1) for guiding the first outer peripheral edge portion and the second deformed bonding pad (deformed bonding pads BP2a2 and BP2b2) for guiding the second outer peripheral edge portion.

Therefore, the first semiconductor chip CHP1 can be two-dimensionally aligned with the second semiconductor chip CHP2. In plan view, the outer peripheral edge of the die attach film DAF can deviate from the analog circuit ANC. An interface between the die attach film DAF and the resin molding member RMB having a large stress difference does not overlap the analog circuit ANC in plan view. Therefore, the normal operation of the analog circuit ANC can be secured.

In the semiconductor device DEV of the present embodiment, the extension line EXL of the outer peripheral edge of the one or more deformed bonding pads BP2 is located on the outer peripheral edge of the analog circuit ANC in plan view. In plan view, the outer peripheral edge of the first semiconductor chip CHP1 deviates from the extension line EXL of the outer peripheral edge of the one or more deformed bonding pads BP2.

Therefore, by using the one or more deformed bonding pads BP2 as alignment marks of the first semiconductor chip CHP1, the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

In the semiconductor device DEV of the present embodiment, the storage elastic modulus of the die attach film DAF at 150° C. is 20 MPa or less.

Therefore, even if the die attach film DAF contracts when the resin molding member RMB is provided, the outer peripheral edge of the die attach film DAF can deviate from the analog circuit ANC in plan view. An interface between the die attach film DAF and the resin molding member RMB having a large stress difference does not overlap the analog circuit ANC in plan view.

Therefore, the normal operation of the analog circuit ANC can be secured.

The method of manufacturing the semiconductor device DEV of the present embodiment includes a step of providing the die attach film DAF on the first semiconductor chip CHP1 (step S1), and a step of aligning the first semiconductor chip CHP1 with the second semiconductor chip CHP2 (step S2). The second semiconductor chip CHP2 includes the analog circuit ANC, the bonding pad BP1, and one or more deformed bonding pads BP2, a shape of the one or more deformed bonding pads BP2 being different from the bonding pad BP1. In the step of aligning the first semiconductor chip CHP1 (step S2), the one or more deformed bonding pads BP2 are used as alignment marks of the first semiconductor chip CHP1. In the step of aligning the first semiconductor chip CHP1 (step S2), the first semiconductor chip CHP1 is aligned with the second semiconductor chip CHP2 such that the analog circuit ANC is located inside the outer peripheral edge of the die attach film DAF in plan view seen in the stacking direction of the first semiconductor chip CHP1 and the die attach film DAF. The method of manufacturing the semiconductor device DEV of the present embodiment includes a step of attaching the first semiconductor chip CHP1 to the second semiconductor chip CHP2 via the die attach film DAF (step S3), and a step of providing the resin molding member RMB for sealing the first semiconductor chip CHP1, the second semiconductor chip CHP2, and the die attach film DAF (step S6).

The first semiconductor chip CHP1 provided with the die attach film DAF is aligned with the second semiconductor chip CHP2 while using the one or more deformed bonding pads BP2 as alignment marks of the first semiconductor chip CHP1. Therefore, even if the die attach film DAF contracts in the step of providing the resin molding member RMB (step S6), the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

In the method of manufacturing the semiconductor device DEV of the present embodiment, the extension line EXL of the outer peripheral edge of the one or more deformed bonding pads BP2 deviates from the analog circuit ANC in plan view. In the step of aligning the first semiconductor chip CHP1 (step S2), the first semiconductor chip CHP1 is aligned with the second semiconductor chip CHP2 such that the outer peripheral edge of the first semiconductor chip CHP1 is located on the extension line EXL of the outer peripheral edge of the one or more deformed bonding pads BP2 in plan view.

Therefore, even if the die attach film DAF contracts in the step of providing the resin molding member RMB (step S6), the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

In the method of manufacturing the semiconductor device DEV of the present embodiment, the first semiconductor chip CHP1 includes the first corner CN1 and the second corner CN2 located diagonally to the first corner CN1. The one or more deformed bonding pads BP2 include the first deformed bonding pad (deformed bonding pads BP2a1 and BP2a2) and the second deformed bonding pad (deformed bonding pads BP2b1 and BP2b2). In the step of aligning the first semiconductor chip CHP1 (step S2), the first semiconductor chip CHP1 is aligned with the second semiconductor chip CHP2 such that the first corner CN1 is located on the extension line EXL of the outer peripheral edge of the first deformed bonding pad and the second corner CN2 is located on the extension line EXL of the outer peripheral edge of the second deformed bonding pad in plan view.

Therefore, the first semiconductor chip CHP1 can be two-dimensionally aligned with the second semiconductor chip CHP2. In plan view, the outer peripheral edge of the die attach film DAF can deviate from the analog circuit ANC. An interface between the die attach film DAF and the resin molding member RMB having a large stress difference does not overlap the analog circuit ANC in plan view. Therefore, the normal operation of the analog circuit ANC can be secured.

In the method of manufacturing the semiconductor device DEV of the present embodiment, the outer peripheral edge of the first semiconductor chip CHP1 includes a first outer peripheral edge portion and a second outer peripheral edge portion extending in a direction (for example, the second direction DR2) intersecting the first outer peripheral edge portion. The one or more deformed bonding pads BP2 include the first deformed bonding pad (deformed bonding pads BP2a1 and BP2b1) and the second deformed bonding pad (deformed bonding pads BP2a2 and BP2b2). In the step of aligning the first semiconductor chip CHP1, the first semiconductor chip CHP1 is aligned with the second semiconductor chip CHP2 such that the first outer peripheral edge portion is located on the extension line EXL of the outer peripheral edge of the first deformed bonding pad and the second outer peripheral edge portion is located on the extension line EXL of the outer peripheral edge of the second deformed bonding pad in plan view.

Therefore, the first semiconductor chip CHP1 can be two-dimensionally aligned with the second semiconductor chip CHP2. In plan view, the outer peripheral edge of the die attach film DAF can deviate from the analog circuit ANC. An interface between the die attach film DAF and the resin molding member RMB having a large stress difference does not overlap the analog circuit ANC in plan view. Therefore, the normal operation of the analog circuit ANC can be secured.

In the method of manufacturing the semiconductor device DEV of the present embodiment, the extension line EXL of the outer peripheral edge of the one or more deformed bonding pads BP2 is located on the outer peripheral edge of the analog circuit ANC in plan view. In the step of aligning the first semiconductor chip CHP1 (step S2), the first semiconductor chip CHP1 is aligned with the second semiconductor chip CHP2 such that the outer peripheral edge of the first semiconductor chip CHP1 deviates from the extension line EXL of the outer peripheral edge of the one or more deformed bonding pads BP2 in plan view.

Therefore, even if the die attach film DAF contracts in the step of providing the resin molding member RMB (step S6), the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

In the method of manufacturing the semiconductor device DEV of the present embodiment, the storage elastic modulus of the die attach film DAF at the mold temperature in the step of providing the resin molding member RMB (step S6) is smaller than the injection pressure of the molding resin in the step of providing the resin molding member RMB (step S6).

Therefore, even if the die attach film DAF contracts in the step of providing the resin molding member RMB (step S6), the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

### Second Embodiment

A configuration of a semiconductor device DEV according to a second embodiment will be described with reference to FIGS. 2 and 11. The semiconductor device DEV of the present embodiment has the same configuration as that of the semiconductor device DEV of the first embodiment, but is different from the semiconductor device DEV of the first embodiment mainly in the following points.

In the present embodiment, the second semiconductor chip CHP2 does not include the deformed bonding pad BP2 (refer to FIG. 1). In the present embodiment, all the bonding pads are the bonding pads BP1.

The second semiconductor chip CHP2 further includes at least one passive electronic element PED. The second semiconductor chip CHP2 may include a plurality of passive electronic elements PED. In the present embodiment, the second semiconductor chip CHP2 includes two passive electronic elements PED. The passive electronic element PED is formed on the front surface of the chip main body CBD on the main surface MSF side. The passive electronic element PED is, for example, a capacitive cell or a diffusion resistor.

The passive electronic element PED is an alignment mark of the first semiconductor chip CHP1. In plan view, the passive electronic element PED has, for example, an L-shape. In plan view, the passive electronic element PED is not particularly limited, but may have a cross shape. One of the two passive electronic elements PED is used for alignment of the first corner CN1 of the first semiconductor chip. The other of the two passive electronic elements PED is used to align the second corner CN2 of the first semiconductor chip located diagonally to the first corner CN1.

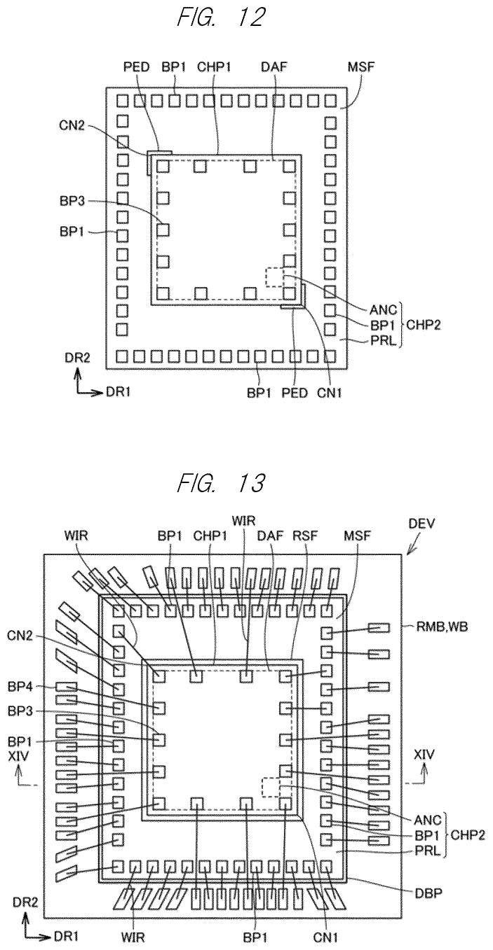

Referring to FIGS. 3 and 12, an example of the method of manufacturing the semiconductor device DEV of the present embodiment includes steps similar to those of the example of the method of manufacturing the semiconductor device DEV of the first embodiment, but mainly step S2 is different from the example of the method of manufacturing the semiconductor device DEV of the first embodiment.

In step S2 of the present embodiment, the first semiconductor chip CHP1 is aligned with the second semiconductor chip CHP2 while using the passive electronic element PED as an semiconductor alignment mark of the first chip CHP1. Specifically, the second semiconductor chip CHP2 includes a plurality of passive electronic elements PED. In plan view, the first corner CN1 of the first semiconductor chip CHP1 is aligned with a corresponding one of the plurality of passive electronic corner CN2 elements PED, and the second of the first semiconductor chip CHP1 is aligned with a corresponding one of the plurality of passive electronic elements PED. For example, the first semiconductor chip CHP1 can be aligned with the second semiconductor chip CHP2 such that a distance between the analog circuit and the outer peripheral edge of the die attach film DAF in plan view is larger than a contraction length of the die attach film DAF in the step of providing the resin molding member RMB (step S6).

In this way, the first semiconductor chip CHP1 can be aligned with the second semiconductor chip CHP2 such that the outer peripheral edge of the die attach film DAF deviates from the analog circuit ANC in plan view.

The semiconductor device DEV and the method of manufacturing the semiconductor device DEV of the present embodiment achieve the following effects similar to the effects of the semiconductor device DEV and the method of manufacturing the semiconductor device DEV of the first embodiment.

The semiconductor device DEV of the present embodiment includes the first semiconductor chip CHP1, the die attach film DAF provided on the first semiconductor chip CHP1, the second semiconductor chip CHP2, and the resin molding member RMB. The first semiconductor chip CHP1 is attached to the second semiconductor chip CHP2 via the die attach film DAF. The second semiconductor chip CHP2 includes the analog circuit ANC and the passive electronic element PED. The passive electronic element PED is an alignment mark of the first semiconductor chip CHP1. In plan view seen in the stacking direction of the first semiconductor chip CHP1 and the die attach film DAF, the analog circuit ANC is located inside the outer peripheral edge of the die attach film DAF. The resin molding member RMB seals the first semiconductor chip CHP1, the second semiconductor chip CHP2, and the die attach film DAF.

By using the passive electronic element PED as an alignment mark of the first semiconductor chip CHP1, the first semiconductor chip CHP1 provided with the die attach film DAF is aligned with the second semiconductor chip CHP2. Therefore, even if the die attach film DAF contracts when the resin molding member RMB is provided, the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

The method of manufacturing the semiconductor device DEV of the present embodiment includes a step of providing the die attach film DAF on the first semiconductor chip CHP1 (step S1), and a step of aligning the first semiconductor chip CHP1 with the second semiconductor chip CHP2 (step S2). The second semiconductor chip CHP2 includes the analog circuit ANC and the passive electronic element PED. In the step of aligning the first semiconductor chip CHP1 (step S2), the passive electronic element PED is used as an alignment mark of the first semiconductor chip CHP1. In the step of aligning the first semiconductor chip CHP1 (step S2), the first semiconductor chip CHP1 is aligned with the second semiconductor chip CHP2 such that the analog circuit ANC is located inside the outer peripheral edge of the die attach film DAF in plan view seen in the stacking direction of the first semiconductor chip CHP1 and the die attach film DAF. The method of manufacturing the semiconductor device DEV of the present embodiment includes a step of attaching the first semiconductor chip CHP1 to the second semiconductor chip CHP2 via the die attach film DAF (step S3), and a step of providing the resin molding member RMB for sealing the first semiconductor chip CHP1, the second semiconductor chip CHP2, and the die attach film DAF (step S6).

While the passive electronic element PED is used as an alignment mark of the first semiconductor chip CHP1, the first semiconductor chip CHP1 provided with the die attach film DAF is aligned with the second semiconductor chip CHP2. Therefore, even if the die attach film DAF contracts in the step of providing the resin molding member RMB (step S6), the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

### Third Embodiment

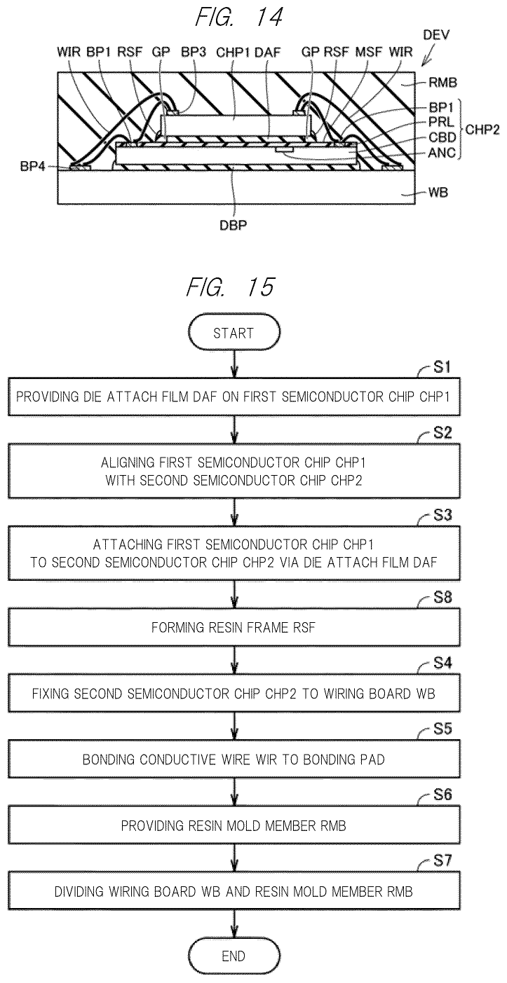

A configuration of a semiconductor device DEV according to a third embodiment will be described with reference to FIGS. 13 and 14. The semiconductor device DEV of the present embodiment has the same configuration as that of the semiconductor device DEV of the first embodiment, but is different from the semiconductor device DEV of the first embodiment mainly in the following points.

In the present embodiment, the second semiconductor chip CHP2 does not include the deformed bonding pad BP2 (refer to FIG. 11). The semiconductor device DEV further includes a resin frame RSF.

In plan view, the resin frame RSF surrounds the die attach film DAF, and separates the die attach film DAF from the resin molding member RMB. For example, a gap GP defined by the first semiconductor chip CHP1, the second semiconductor chip CHP2, and the die attach film DAF is filled with the resin frame RSF.

The resin frame RSF includes, for example, a thermosetting resin and a filler dispersed in the thermosetting resin. The thermosetting resin is, for example, an epoxy resin. The filler is, for example, silica particles. The filler content of the resin frame RSF is lower than the filler content of the resin molding member RMB. The filler content of the resin molding member RMB is, for example, 50 weight percent or more and less than 70 weight percent. The storage elastic modulus of the resin frame RSF at 150° C. is larger than the storage elastic modulus of the die attach film DAF at 150° C.

The resin molding member RMB seals the first semiconductor chip CHP1, the second semiconductor chip CHP2, the die attach film DAF, and the resin frame RSF.

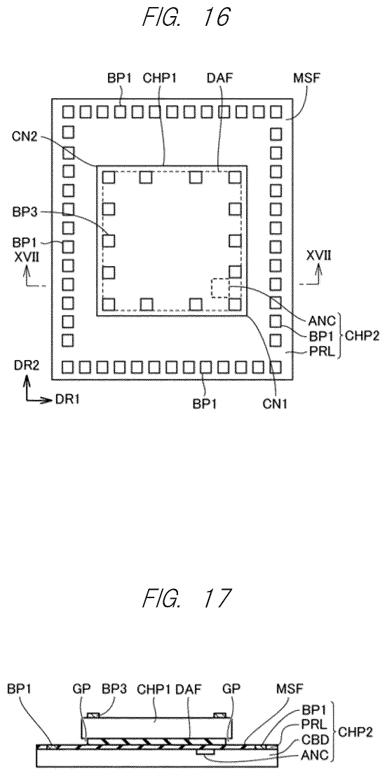

Referring to FIGS. 15 to 17, the example of the method of manufacturing the semiconductor device DEV of the present embodiment includes the same steps as those of the example of the method of manufacturing the semiconductor device DEV of the first embodiment, but is different from the example of the method of manufacturing the semiconductor device DEV of the first embodiment mainly in the following.

Referring to FIG. 15, the die attach film DAF is provided on the first semiconductor chip CHP1 (step S1). Step S1 of the present embodiment is similar to step S1 (refer to FIG. 3) of the first embodiment, but in plan view seen in the stacking direction of the first semiconductor chip CHP1 and the die attach film DAF, the outer peripheral edge of the die attach film DAF is located, for example, inside the outer peripheral edge of the first semiconductor chip CHP1.

Referring to FIGS. 15 to 17, the first semiconductor chip CHP1 is aligned with the second semiconductor chip CHP2 (step S2). Specifically, the first semiconductor chip CHP1 is aligned with the second semiconductor chip CHP2 such that the analog circuit ANC is located inside the outer peripheral edge of the die attach film DAF in plan view. In plan view, the outer peripheral edge of the die attach film DAF deviates from the analog circuit ANC.

Referring to FIG. 15, the first semiconductor chip CHP1 is attached to the second semiconductor chip CHP2 via the die attach film DAF (step S3). Step S3 of the present embodiment is similar to step S3 of the first embodiment (refer to FIG. 3), but the gap GP is formed by the first semiconductor chip CHP1, the second semiconductor chip CHP2, and the die attach film DAF.

Referring to FIG. 15, the resin frame RSF is formed (step S8). For example, using a dispenser (not illustrated), a filler-containing resin is supplied around the die attach film DAF. For example, the gap GP is filled with the filler-containing resin. The filler-containing resin is heated to cure the filler-containing resin. Thus, the resin frame RSF is formed.

Referring to FIG. 15, the second semiconductor chip CHP2 is fixed to the wiring board WB using the die-bonding paste DBP or the die attach film (not illustrated) (step S4). Step S4 of the present embodiment is similar to step S4 of the first embodiment.

Referring to FIG. 15, the conductive wire WIR is bonded to the bonding pad (step S5). Specifically, the conductive wire WIR is bonded to the bonding pads BP1, BP3, and BP4.

Referring to FIG. 15, the resin molding member RMB is provided (step S6). Step S6 of the present embodiment is similar to step S6 of the first embodiment, but in the present embodiment, the resin molding member RMB seals the first semiconductor chip CHP1, the second semiconductor chip CHP2, the die attach film DAF, and the resin frame RSF.

Referring to FIG. 15, the wiring board WB and the resin molding member RMB are divided, and the stacked body including the first semiconductor chip CHP1, the second semiconductor chip CHP2, and the wiring board WB is divided into individual pieces (step S7). Step S7 of the present embodiment is similar to step S7 of the first embodiment. Thus, the semiconductor device DEV of the present embodiment is obtained.

Functions of the semiconductor device DEV and the method of manufacturing the semiconductor device DEV of the present embodiment will be described.

The storage elastic modulus of the die attach film DAF at the mold temperature (for example, 150° C.) is smaller than the injection pressure of the molding resin. On the other hand, the storage elastic modulus of the resin frame RSF at the mold temperature (for example, 150° C.) s larger than the storage elastic modulus of the die attach film DAF, and is equal to or higher than the injection pressure of the molding resin. Therefore, even if the resin frame RSF is pushed by the molding resin when the molding resin is injected, the resin frame RSF does not contract and functions as a weir for the molding resin. The resin frame RSF can prevent the die attach film DAF from contracting. In plan view, the outer peripheral edge of the die attach film DAF is still located outside the analog circuit ANC and deviates from the analog circuit ANC. Since the resin frame RSF is located between the die attach film DAF and the molding resin, an interface between the die attach film DAF and the resin molding member RMB having a large stress difference does not overlap the analog circuit ANC in plan view. Therefore, the normal operation of the analog circuit ANC can be secured.

The semiconductor device DEV and the method of manufacturing the semiconductor device DEV of the present embodiment achieve the following effects similar to the effects of the semiconductor device DEV and the method of manufacturing the semiconductor device DEV of the first embodiment.

The semiconductor device DEV of the present embodiment includes the first semiconductor chip CHP1, the die attach film DAF provided on the first semiconductor chip CHP1, the second semiconductor chip CHP2, the resin frame RSF, and the resin molding member RMB. The first semiconductor chip CHP1 is attached to the second semiconductor chip CHP2 via the die attach film DAF. The second semiconductor chip CHP2 includes the analog circuit ANC. The resin frame RSF surrounds the die attach film DAF in plan view seen in the stacking direction of the first semiconductor chip CHP1 and the die attach film DAF, and separates the die attach film DAF from the resin molding member RMB. The storage elastic modulus of the resin frame RSF at 150° C. is larger than the storage elastic modulus of the die attach film DAF at 150° C. In plan view, the analog circuit ANC is located inside the outer peripheral edge of the die attach film DAF. The resin molding member RMB seals the first semiconductor chip CHP1, the second semiconductor chip CHP2, the die attach film DAF, and the resin frame RSF.

The method of manufacturing the semiconductor device DEV of the present embodiment includes a step of providing the die attach film DAF on the first semiconductor chip CHP1 (step S1), and a step of aligning the first semiconductor chip CHP1 with the second semiconductor chip CHP2 (step S2). The second semiconductor chip CHP2 includes the analog circuit ANC. In the step of aligning the first semiconductor chip CHP1 (step S2), the first semiconductor chip CHP1 is aligned with the second semiconductor chip CHP2 such that the analog circuit ANC is located inside the outer peripheral edge of the die attach film DAF in plan view seen in the stacking direction of the first semiconductor chip CHP1 and the die attach film DAF. The method of manufacturing the semiconductor device DEV of the present embodiment includes a step of attaching the first semiconductor chip CHP1 to the second semiconductor chip CHP2 via the die attach film DAF (step S3), and a step of forming the resin frame RSF surrounding the die attach film DAF in plan view (step S8). The storage elastic modulus of the resin frame RSF at 150° C. is larger than the storage elastic modulus of the die attach film DAF at 150° C. The method of manufacturing the semiconductor device DEV of the present embodiment includes a step of providing the resin molding member RMB for sealing the first semiconductor chip CHP1, the second semiconductor chip CHP2, the die attach film DAF, and the resin frame RSF (step S6).

The resin frame RSF functions as a weir for the molding resin injected to form the resin molding member RMB. When the resin molding member RMB is formed, the resin frame RSF prevents the die attach film DAF from contracting. Therefore, the outer peripheral edge of the die attach film DAF can deviate from the analog circuit ANC in plan view. Since the resin frame RSF is located between the die attach film DAF and the molding resin, an interface between the die attach film DAF and the resin molding member RMB having a large stress difference does not overlap the analog circuit ANC in plan view. Therefore, the normal operation of the analog circuit ANC can be secured.

### Fourth Embodiment

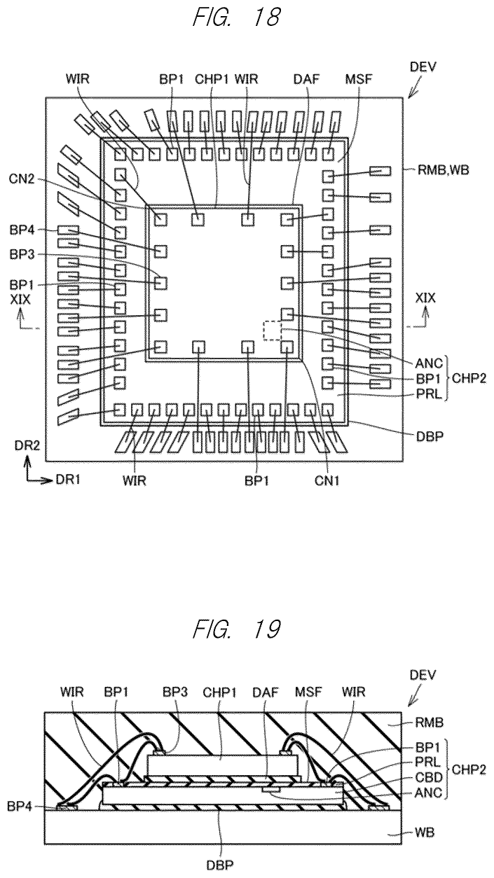

A configuration of a semiconductor device DEV according to a fourth embodiment will be described with reference to FIGS. 18 and 19. The semiconductor device DEV of the present embodiment has the same configuration as that of the semiconductor device DEV of the first embodiment, but is different from the semiconductor device DEV of the first embodiment mainly in the following points.

In the present embodiment, the second semiconductor chip CHP2 does not include the deformed bonding pad BP2 (refer to FIG. 11). In plan view seen in the stacking direction of the first semiconductor chip CHP1 and the die attach film DAF, the outer peripheral edge of the die attach film DAF is located outside the outer peripheral edge of the first semiconductor chip CHP1. In plan view, the analog circuit ANC is located inside the outer peripheral edge of the die attach film DAF and inside the outer peripheral edge of the first semiconductor chip CHP1.

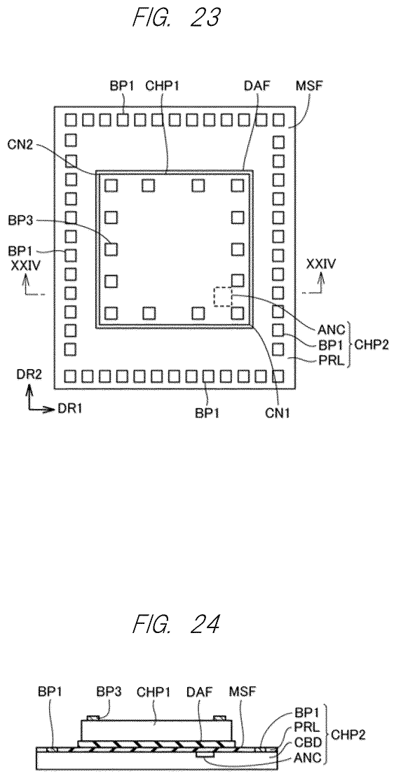

An example of a method of manufacturing the semiconductor device DEV of the present embodiment will be described with reference to FIGS. 3 and 20 to 24. The example of the method of manufacturing the semiconductor device DEV of the present embodiment includes the same steps as those of the example of the method of manufacturing the semiconductor device DEV of the first embodiment, but is different from the example of the method of manufacturing the semiconductor device DEV of the first embodiment mainly in the following.

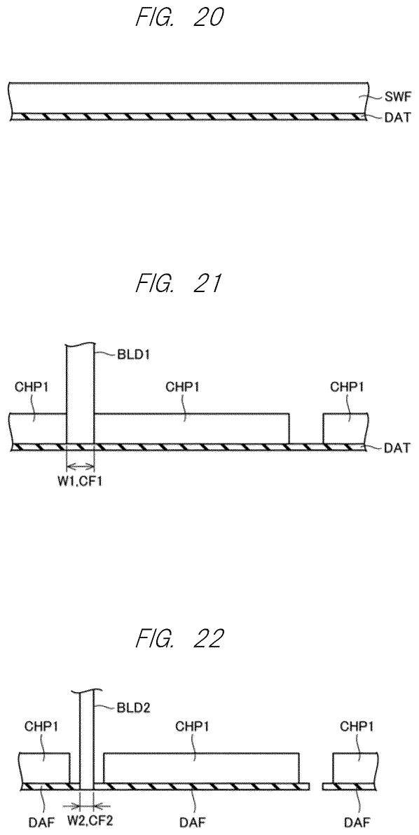

Referring to FIG. 3, the die attach film DAF is provided on the first semiconductor chip CHP1 (step S1). In the present embodiment, in plan view seen in the stacking direction of the first semiconductor chip CHP1 and the die attach film DAF, the outer peripheral edge of the die attach film DAF is located outside the outer peripheral edge of the first semiconductor chip CHP1. An example of a method of providing the die attach film DAF on the first semiconductor chip CHP1 will be described with reference to FIGS. 20 to 22.

Referring to FIG. 20, a die attach tape DAT is attached to a semiconductor wafer SWF. A plurality of first semiconductor chips CHP1 is formed on the semiconductor wafer SWF such as a silicon wafer.

Referring to FIG. 21, the semiconductor wafer SWF is cut to singulate the semiconductor wafer SWF into a plurality of first semiconductor chips CHP1. For example, the semiconductor wafer SWF is cut using a first blade BLD1. The die attach tape DAT is not cut by the first blade BLD1.

Referring to FIG. 22, the die attach tape DAT is cut to separate the die attach tape DAT into a plurality of die attach films DAF. For example, the die attach tape DAT is cut using a second blade BLD2. The first semiconductor chip CHP1 is not cut by the second blade BLD2. Cutting allowance CF2 of the die attach tape DAT is narrower than cutting allowance CF1 of the semiconductor wafer SWF. For example, a width W2 of the second blade BLD2 is narrower than a width W1 of the first blade BLD1. Therefore, in plan view seen in the stacking direction of the first semiconductor chip CHP1 and the die attach film DAF, the outer peripheral edge of the die attach film DAF is located, for example, outside the outer peripheral edge of the first semiconductor chip CHP1.

Referring to FIG. 3, the first semiconductor chip CHP1 is aligned with the second semiconductor chip CHP2 (step S2). Specifically, the first semiconductor chip CHP1 is aligned with the second semiconductor chip CHP2 such that the analog circuit ANC is located inside the outer peripheral edge of the die attach film DAF and inside the first semiconductor chip CHP1 in plan view. In plan view, the outer peripheral edge of the die attach film DAF deviates from the analog circuit ANC.

Referring to FIGS. 3, 23, and 24, the first semiconductor chip CHP1 is attached to the second semiconductor chip CHP2 via the die attach film DAF (step S3). Step S3 of the present embodiment is similar to step S3 of the first embodiment (refer to FIG. 3), but the outer peripheral edge of the die attach film DAF is located outside the outer peripheral edge of the first semiconductor chip CHP1 in plan view.

Referring to FIG. 3, the second semiconductor chip CHP2 is fixed to the wiring board WB using the die-bonding paste DBP or the die attach film (not illustrated) (step S4). The conductive wire WIR is bonded to the bonding pad (step S5). Steps S4 and S5 of the present embodiment are similar to steps S4 and S5 of the third embodiment (refer to FIG. 15).

Referring to FIG. 3, the resin molding member RMB for sealing the first semiconductor chip CHP1, the second semiconductor chip CHP2, and the die attach film DAF is provided (step S6). Step S6 of the present embodiment is similar to step S6 of the first embodiment.

Referring to FIG. 3, the wiring board WB and the resin molding member RMB are divided, and the stacked body including the first semiconductor chip CHP1, the second semiconductor chip CHP2, and the wiring board WB is divided into individual pieces (step S7). Step S7 of the present embodiment is similar to step S7 of the first embodiment. Thus, the semiconductor device DEV of the present embodiment is obtained.

Functions of the semiconductor device DEV and the method of manufacturing the semiconductor device DEV of the present embodiment will be described.

The storage elastic modulus of the die attach film DAF at the mold temperature (for example, 150° C.) is smaller than the injection pressure of the molding resin. Therefore, when the molding resin is injected, the die attach film DAF is pushed by the molding resin, resulting in contraction of die attach film. However, in the step of attaching the first semiconductor chip CHP1 to the main surface MSF of the second semiconductor chip CHP2 (step S3), the outer peripheral edge of the die attach film DAF is located outside the outer peripheral edge of the first semiconductor chip CHP1 in plan view.

Therefore, even if the die attach film DAF contracts when the molding resin is injected, the outer peripheral edge of the die attach film DAF is still located outside the analog circuit ANC and deviates from the analog circuit ANC in plan view. An interface between the die attach film DAF and the resin molding member RMB does not overlap the analog circuit ANC in plan view. Therefore, the normal operation of the analog circuit ANC can be secured.

In the present embodiment, the outer peripheral edge of the die attach film DAF may be located outside the outer peripheral edge of the first semiconductor chip CHP1 in step S3, the outer peripheral edge of the die attach film DAF may be located outside the analog circuit ANC after step S6, and the outer peripheral edge of the die attach film DAF may be located inside the outer peripheral edge of the first semiconductor chip CHP1 after step S6.

The effects of the semiconductor device DEV and the method of manufacturing the semiconductor device DEV of the present embodiment achieve the following effects similar to the effects of the semiconductor device DEV and the method of manufacturing the semiconductor device DEV of the first embodiment.

The semiconductor device DEV of the present embodiment includes the first semiconductor chip CHP1, the die attach film DAF provided on the first semiconductor chip CHP1, the second semiconductor chip CHP2, and the resin molding member RMB. The first semiconductor chip CHP1 is attached to the second semiconductor chip CHP2 via the die attach film DAF. The second semiconductor chip CHP2 includes the analog circuit ANC. In plan view seen in the stacking direction of the first semiconductor chip CHP1 and the die attach film DAF, the outer peripheral edge of the die attach film DAF is located outside the outer peripheral edge of the first semiconductor chip CHP1. In plan view, the analog circuit ANC is located inside the outer peripheral edge of the die attach film DAF and inside the outer peripheral edge of the first semiconductor chip CHP1. The resin molding member RMB seals the first semiconductor chip CHP1, the second semiconductor chip CHP2, and the die attach film DAF.

The method of manufacturing the semiconductor device DEV of the present embodiment includes a step of providing the die attach film DAF on the first semiconductor chip CHP1 (step S1). In plan view seen in the stacking direction of the first semiconductor chip CHP1 and the die attach film DAF, the outer peripheral edge of the die attach film DAF is located outside the outer peripheral edge of the first semiconductor chip CHP1. The method of manufacturing the semiconductor device DEV of the present embodiment includes a s step of aligning the first semiconductor chip CHP1 with the second semiconductor chip CHP2 The second semiconductor chip CHP2 includes the (step S2). analog circuit ANC. In the step of f aligning the first semiconductor chip CHP1 (step S2), the first semiconductor chip CHP1 is aligned with the second semiconductor chip CHP2 such that the analog circuit ANC is located inside the outer peripheral edge of the die attach film DAF and inside the outer peripheral edge of the first semiconductor chip CHP1 in plan view. The method of manufacturing the semiconductor device DEV of the present embodiment includes a step of attaching the first semiconductor chip CHP1 to the second semiconductor chip CHP2 via the die attach film DAF (step S3), and a step of providing the resin molding member RMB for sealing the first semiconductor chip CHP1, the second semiconductor chip CHP2, and the die attach film DAF (step S6).

Therefore, even if the die attach film DAF contracts when the resin molding member RMB is formed, the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

In the method of manufacturing the semiconductor device DEV of the present embodiment, the step of providing the die attach film DAF on the first semiconductor chip CHP1 (step S1) includes a step of attaching the die attach tape DAT to the semiconductor wafer SWF. The step of providing the die attach film DAF on the first semiconductor chip CHP1 (step S1) includes a step of cutting the semiconductor wafer SWF to singulate the semiconductor wafer SWF into a plurality of first semiconductor chips CHP1, and a step of cutting the die attach tape DAT to separate the die attach tape DAT into a plurality of die attach films DAF. Cutting allowance CF2 of the die attach tape DAT is narrower than cutting allowance CF1 of the semiconductor wafer SWF.

Therefore, in plan view seen in the stacking direction of the first semiconductor chip CHP1 and the die attach film DAF, the outer peripheral edge of the die attach film DAF can be located outside the outer peripheral edge of the first semiconductor chip CHP1. Even if the die attach film DAF contracts in the step of providing the resin molding member RMB (step S6), the outer peripheral edge of the die attach film DAF can deviate from the analog circuit ANC in plan view. An interface between the die attach film DAF and the resin molding member RMB having a large stress difference does not overlap the analog circuit ANC in plan view. Therefore, the normal operation of the analog circuit ANC can be secured.

### Fifth Embodiment

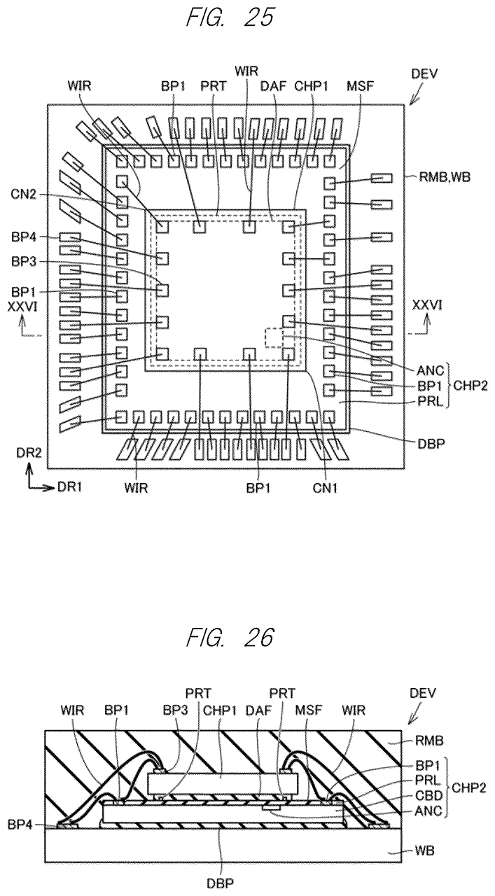

A configuration of a semiconductor device DEV according to a fifth embodiment will be described with reference to FIGS. 25 and 26. The semiconductor device DEV of the present embodiment has the same configuration as that of the semiconductor device DEV of the embodiment, first but is different from the semiconductor device DEV of the first embodiment mainly in the following points.

In the present embodiment, the second semiconductor chip CHP2 does not include the deformed bonding pad BP2 (refer to FIG. 11). A protrusion PRT is provided on the protective layer PRL. The protrusion PRT is formed of, for example, the same material as that of the protective layer PRL. The protective layer PRL having the protrusion PRT may be formed by applying a resin to be the protective layer PRL twice, or may be formed by etching a part of the protective layer PRL.

In plan view seen in the stacking direction of the first semiconductor chip CHP1 and the die attach film DAF, the protrusion PRT is disposed inside the outer peripheral edge of the die attach film DAF. In plan view, the protrusion PRT extends along the outer peripheral edge of the die attach film DAF. In plan view, the protrusion PRT surrounds the analog circuit ANC. In plan view, the analog circuit ANC is located inside the protrusion PRT. A part of the die attach film DAF is engaged with the protrusion PRT.

An example of a method of manufacturing the semiconductor device DEV of the present embodiment will be described with reference to FIG. 3. The example of the method of manufacturing the semiconductor device DEV of the present embodiment includes the same steps as those of the example of the method of manufacturing the semiconductor device DEV of the first embodiment, but is different from the example of the method of manufacturing the semiconductor device DEV of the first embodiment mainly in the following.

Referring to FIG. 3, the first semiconductor chip CHP1 is aligned with the second semiconductor chip CHP2 (step S2). Specifically, the first semiconductor chip CHP1 is aligned with the second semiconductor chip CHP2 such that the analog circuit ANC is located inside the outer peripheral edge of the die attach film DAF and inside the protrusion PRT in plan view. In plan view, the outer peripheral edge of the die attach film DAF deviates from the analog circuit ANC. In plan view, the protrusion PRT overlaps the die attach film DAF and surrounds the analog circuit ANC.

Referring to FIG. 3, the first semiconductor chip CHP1 is attached to the second semiconductor chip CHP2 via the die attach film DAF (step S3). Step S3 of the present embodiment is similar to step S3 of the first embodiment (refer to FIG. 3), but a part of the die attach film DAF is engaged with the protrusion PRT.

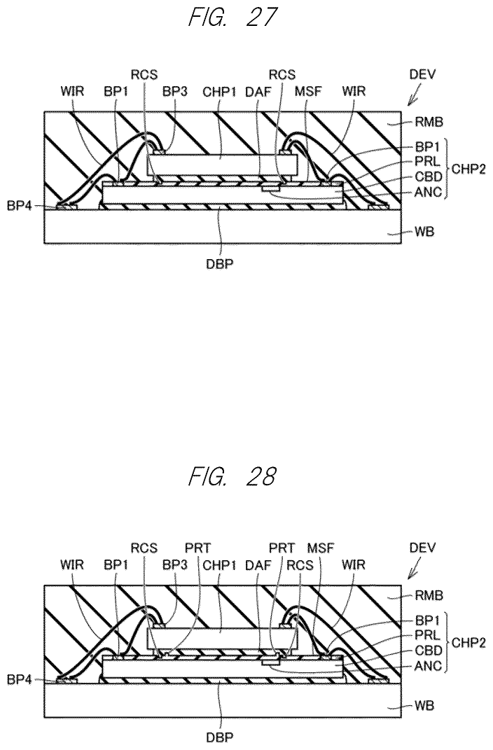

Referring to FIG. 27, in the semiconductor device DEV of a first modification of the present embodiment, the protective layer PRL is provided with a recess RCS instead of the protrusion PRT. The protective layer PRL having the recess RCS may be formed by applying a resin to be the protective layer PRL twice, or may be formed by etching a part of the protective layer PRL. A part of the die attach film DAF is engaged with the recess RCS.

Referring to FIG. 28, in the semiconductor device DEV of a second modification of the present embodiment, both the protrusion PRT and the recess RCS are provided in the protective layer PRL. The protrusion PRT is disposed inside the recess RCS. The recess RCS may be disposed outside the protrusion PRT. A part of the die attach film DAF is engaged with at least one of the protrusion PRT or the recess RCS.

Functions of the semiconductor device DEV and the method of manufacturing the semiconductor device DEV of the present embodiment will be described.

The storage elastic modulus of the die attach film DAF at the mold temperature (for example, 150° C.) is smaller than the injection pressure of the molding resin. Therefore, when the molding resin is injected, the die attach film DAF is pushed by the molding resin, resulting in contraction of die attach film. However, the analog circuit ANC is surrounded by at least one of the protrusion PRT or the recess RCS of the protective layer PRL. A part of the die attach film DAF is engaged with at least one of the protrusion PRT or the recess RCS of the protective layer PRL.

Therefore, even if the die attach film DAF contracts when the molding resin is injected, the die attach film DAF is prevented from contracting to the inside of at least one of the protrusion PRT or the recess RCS. In plan view, the outer peripheral edge of the die attach film DAF is still located outside the analog circuit ANC and deviates from the analog circuit ANC. An interface between the die attach film DAF and the resin molding member RMB having a large stress difference does not overlap the analog circuit ANC in plan view. Therefore, the normal operation of the analog circuit ANC can be secured.

The effects of the semiconductor device DEV and the method of manufacturing the semiconductor device DEV of the present embodiment achieve the following effects similar to the effects of the semiconductor device DEV and the method of manufacturing the semiconductor device DEV of the first embodiment.

The semiconductor device DEV of the present embodiment includes the first semiconductor chip CHP1, the die attach film DAF formed on the first semiconductor chip CHP1, the second semiconductor chip CHP2, and the resin molding member RMB. The first semiconductor chip CHP1 is attached to the second semiconductor chip CHP2 via the die attach film DAF. The second semiconductor chip CHP2 includes the analog circuit ANC and the protective layer PRL covering the analog circuit ANC. At least one of the protrusion PRT or the recess RCS is provided in the protective layer PRL. A part of the die attach film DAF is engaged with at least one of the protrusion PRT or the recess RCS. In plan view seen in the stacking direction of the first semiconductor chip CHP1 and the die attach film DAF, the analog circuit ANC is located inside the outer peripheral edge of the die attach film DAF and inside at least one of the protrusion PRT or the recess RCS. The resin molding member RMB seals the first semiconductor chip CHP1, the second semiconductor chip CHP2, and the die attach film DAF.

The method of manufacturing the semiconductor device DEV of the present embodiment includes a step of providing the die attach film DAF on the first semiconductor chip CHP1 (step S1), and a step of aligning the first semiconductor chip CHP1 with the second semiconductor chip CHP2 (step S2). The second semiconductor chip CHP2 includes the analog circuit ANC and the protective layer PRL covering the analog circuit ANC. At least one of the protrusion PRT or the recess RCS is provided in the protective layer PRL. In the step of aligning the first semiconductor chip CHP1 (step S2), the first semiconductor chip CHP1 is aligned with the second semiconductor chip CHP2 such that the analog circuit ANC is located inside the outer peripheral edge of the die attach film DAF and inside at least one of the protrusion PRT or the recess RCS in plan view seen in the stacking direction of the first semiconductor chip CHP1 and the die attach film DAF. The method of manufacturing the semiconductor device DEV of the present embodiment includes a step of attaching the first semiconductor chip CHP1 to the second semiconductor chip CHP2 via the die attach film DAF (step S3). A part of the die attach film DAF is engaged with at least one of the protrusion PRT or the recess RCS. The method of manufacturing the semiconductor device DEV of the present embodiment includes a step of providing the resin molding member RMB for sealing the first semiconductor chip CHP1, the second semiconductor chip CHP2, and the die attach film DAF (step S6).

When the resin molding member RMB is formed, the die attach film DAF contracts. However, the analog circuit ANC is surrounded by at least one of the protrusion PRT or the recess RCS of the protective layer PRL. The die attach film DAF is engaged with at least one of the protrusion PRT or the recess Therefore, the die attach film DAF is prevented from RCS. contracting to the inside of at least one of the recess RCS or the protrusion PRT. In plan view, the outer peripheral edge of the die attach film DAF is still located outside the analog circuit ANC and deviates from the analog circuit ANC. An interface between the die attach film DAF and the resin molding member RMB having a large stress difference does not overlap the analog circuit ANC in plan view. Therefore, the normal operation of the analog circuit ANC can be secured.

Although the invention made by the present inventors has been specifically described based on the embodiments, the present invention is not limited to the above embodiments, and it goes without saying that various modifications can be made without departing from the gist of the present invention.

What is claimed is:

1. A semiconductor device comprising:
a first semiconductor chip;
a die attach film provided on the first semiconductor chip;
a second semiconductor chip; and
a resin molding member sealing the first semiconductor chip, the second semiconductor chip, and the die attach film,
wherein the first semiconductor chip is attached to the second semiconductor chip via the die attach film,
wherein the second semiconductor chip includes an analog circuit, a bonding pad, and one or more deformed bonding pads, a shape of the one or more deformed bonding pads being different from a shape of the bonding pad,
wherein the one or more deformed bonding pads are alignment marks of the first semiconductor chip, and
wherein the analog circuit is located inside an outer peripheral edge of the die attach film in plan view seen in a stacking direction of the first semiconductor chip and the die attach film.

2. The semiconductor device according to claim 1,
wherein an extension line of an outer peripheral edge of the one or more deformed bonding pads deviates from the analog circuit in plan view, and
wherein an outer peripheral edge of the first semiconductor chip is located on the extension line in plan view.

3. The semiconductor device according to claim 2,
wherein the first semiconductor chip includes a first corner and a second corner located diagonally to the first corner, and
wherein the one or more deformed bonding pads include: a first deformed bonding pad for alignment of the first corner; and a second deformed bonding pad for alignment of the second corner.

4. The semiconductor device according to claim 2,
wherein the outer peripheral edge of the first semiconductor chip includes: a first outer peripheral edge portion; and a second outer peripheral edge portion extending in a direction intersecting the first outer peripheral edge portion, and
wherein the one or more deformed bonding pads include: a first deformed bonding pad configured to guide the first outer peripheral edge portion; and a second deformed bonding pad configured to guide the second outer peripheral edge portion.

5. The semiconductor device according to claim 1,
wherein an extension line of an outer peripheral edge of the one or more deformed bonding pads is located on an outer peripheral edge of the analog circuit in plan view, and
wherein an outer peripheral edge of the first semiconductor chip deviates from the extension line in plan view.

6. The semiconductor device according to claim 1,
wherein a storage elastic modulus of the die attach film at 150° C. is 20 MPa or less.

7. A method of manufacturing a semiconductor device, the method comprising:
a step of providing attach film on a first semiconductor chip;
a step of aligning the first semiconductor chip with a second semiconductor chip;
a step of attaching the first semiconductor chip to the second semiconductor chip via the die attach film; and
a step of providing a resin molding member sealing the first semiconductor chip, the second semiconductor chip, and the die attach film,
wherein the second semiconductor chip includes an analog circuit, a bonding pad, and one or more deformed bonding pads, a shape of the one or more deformed bonding pads being different from a shape of the bonding pad, and
wherein, in the step of aligning the first semiconductor chip, the first semiconductor chip is aligned with the second semiconductor chip such that the analog circuit is located inside an outer peripheral edge of the die attach film in plan view seen in a stacking direction of the first semiconductor chip and the die attach film while using the one or more deformed bonding pads as alignment marks of the first semiconductor chip.

8. The method of manufacturing the semiconductor device according to claim 7,
wherein an extension line of an outer peripheral edge of the one or more deformed bonding pads deviates from the analog circuit in plan view, and
wherein, in the step of aligning the first semiconductor chip, the first semiconductor chip is aligned with the second semiconductor chip such that an outer peripheral edge of the first semiconductor chip is located on the extension line in plan view.

9. The method of manufacturing the semiconductor device according to claim 8,
wherein the first semiconductor chip includes a first corner and a second corner located diagonally to the first corner,
wherein the one or more deformed bonding pads include a first deformed bonding pad and a second deformed bonding pad, and
wherein, in the step of aligning the first semiconductor chip, the first semiconductor chip is aligned with the second semiconductor chip such that the first corner is located on an extension line of an outer peripheral edge of the first deformed bonding pad and the second corner is located on an extension line of an outer peripheral edge of the second deformed bonding pad in plan view.

10. The method of manufacturing the semiconductor device according to claim 8,
wherein the outer peripheral edge of the first semiconductor chip includes a first outer peripheral edge portion and a second outer peripheral edge portion extending in a direction intersecting the first outer peripheral edge portion,
wherein the one or more deformed bonding pads include a first deformed bonding pad and a second deformed bonding pad, and
wherein, in the step of aligning the first semiconductor chip, the first semiconductor chip is aligned with the second semiconductor chip such that the first outer peripheral edge portion is located on an extension line of an outer peripheral edge of the first deformed bonding pad and the second outer peripheral edge portion is located on an extension line of an outer peripheral edge of the second deformed bonding pad in plan view.

11. The method of manufacturing the semiconductor device according to claim 7,
wherein an extension line of an outer peripheral edge of the one or more deformed bonding pads is located on an outer peripheral edge of the analog circuit in plan view, and
wherein, in the step of aligning the first semiconductor chip, the first semiconductor chip is aligned with the second semiconductor chip such that an outer peripheral edge of the first semiconductor chip deviates from the extension line in plan view.

12. The method of manufacturing the semiconductor device according to claim 7,
wherein a storage elastic modulus of the die attach film at a mold temperature in the step of providing the resin molding member is smaller than an injection pressure of a molding resin in the step of providing the resin molding member.
